(19) United States
(12) Patent Application Publication
(10) Pub. No.: US 2006/0237811 A1
(43) Pub. Date: Oct. 26, 2006

(54) Non-destructive, in-line characterization of semiconductor materials

(76) Inventors: Boone Thomas, San Jose, CA (US); Hironori Tsukamoto, New Haven, CT (US); Jerry Woodall, New Haven, CT (US)

Correspondence Address: attn: David Garrod;Goodwin Procter LLP, 599 Lexington Avenue, New York, NY, 10022, US

(21) Appl. No.: 11/271,426

(22) Filed: Nov. 10, 2005

Related U.S. Application Data
(60) Provisional application No. 60/626,984, filed on Nov. 10, 2004.

(51) Int. Cl. H01L 31/00

(52) U.S. Cl. 257/442

(57) ABSTRACT

A method for non-destructively determining parameters of a doped semiconductor material involves applying an excitation to a surface of the semiconductor material to photogenerate minority carriers in a region of the semiconductor material, presenting an electric field across the region of the semiconductor material, measuring photoluminescence produced by recombination of the photogenerated minority carriers, and using the photoluminescence measurements to compute one or more parameters of the doped semiconductor material. Excitation may involve pulsed or CW lasers. Computed parameters may include one or more of: the minority carrier mobility of the semiconductor material; the saturation drift velocity of minority carriers in the semiconductor material; the diffusion constant of minority carriers in the semiconductor material; the recombination lifetime of minority carriers in the semiconductor material; and/or the effective temperature of the semiconductor material. An optional magnetic field may be presented across the semiconductor region to enable computation of the effective mass of minority carriers in the semiconductor material.

### CROSS-REFERENCE TO RELATED APPLICATION

This application claims priority from U.S. Provisional Patent Application Ser. No. 60/626,984, filed Nov. 10, 2004, by the inventors herein.

### FIELD OF THE INVENTION

The present invention relates generally to the field of semiconductor manufacturing and process control. More particularly, the invention relates to methods and apparatus for evaluating/monitoring parameters of a semiconductor material using a non-destructive, in-line test.

### BACKGROUND OF THE INVENTION

Manufacturing of modern semiconductor devices involves many process steps. Typical steps include growing layers of various materials, implanting or diffusing dopants into the surface of grown materials, and applying thermal treatments (e.g., annealing) to alter the properties of materials. The detailed sequence of steps, along with the associated parameter settings for each step, is typically referred to as the process recipe.

Recently, semiconductor manufacturers have implemented computerized process controls that vary the process recipe based on measurements of parameters on a partially completed device. See, eg., U.S. Pat. No. 6,197,604, incorporated by reference, at 1:14-25 (“In recent years, the control of semiconductor processes has evolved to include an approach referred to as run-to-run (RtR) control. RtR control is a type of supervisory-level control that uses in-line measurements to adjust the recipe used on a process tool. The recipe adjustments are typically made on a lot-to-lot, wafer-to-wafer, or batch-to-batch basis to compensate for drifting tool qualities or changes in incoming wafer conditions. The in-line measurements are made after the process begins being controlled in the case of feedback control, or before the process in the case of feedforward control.”).

A key to improving the effectiveness of RtR control is the ability to easily and accurately obtain measurements of various semiconductor parameters. Preferably, such measurements should be performed using non-destructive tests. The present invention teaches a new and improved method for measuring various semiconductor parameters using an inexpensive, non-destructive technique. Although the invention is most applicable to semiconductor manufacturing operations, it is also useful in other contexts (such as R&D, post-manufacture testing, etc.) in which the parameters of a semiconductor material need to be measured.

### SUMMARY OF THE INVENTION

Aspects of the present invention are inspired by the classic Haynes-Shockley experiment. In this experiment, a laser pulse is shot onto a semiconductor film to produce excess charge carriers. A potential is applied across the film to sweep the excess carriers across the surface until they are collected by a probe. The signal is carried to an oscilloscope where measurements can be made. A spike is produced on the oscilloscope and the width of the spike determines the diffusion effects. Drift is also measured by comparing the distance the charge carriers travel to the time it takes the excess carriers to travel that distance, and recombination is determined by comparing the charge carrier densities at two different points of collection and determining the time difference.

Based on the principle of the Haynes-Shockley experiment, the invention provides a novel semiconductor parameter characterization technique. It utilizes semiconductor luminescence and lateral electric fields to distribute light-emitting regions. Light is generated within a semiconductor when minority carriers recombine with majority carriers. Minority carriers can be generated within a semiconductor by absorbing light with energy greater than the bandgap energy of the semiconductor. Therefore, if light with high enough energy is focused on a region of a p-type semiconductor, electrons will be generated within the region. These electrons under the influence of no electric fields will diffuse randomly throughout the semiconductor and recombine with majority carrier holes. When recombination occurs, photons will be generated that can be observed externally.

If an electric field is present during the photogeneration process, the minority carriers generated will drift under the influence of the electric field until they recombine with majority carriers, generating a photon. This process will result is spatially relocating the light emissions resulting from the photogenerated carriers. The shape and location of the distribution will be a function of the semiconductor's material parameters.

By mounting a camera over, or by scanning an optical fiber probe along, the photoluminescence emission spot, many of a semiconductor's parameters can be computed. These parameters include the minority carrier mobility, saturation drift velocity, diffusion constant, minority carrier recombination lifetime, and effective temperature. With the addition of a magnetic field, the effective mass of the minority carriers can also be measured.

Accordingly, in light of the above, generally speaking, and without intending to be limiting, one aspect of the invention relates to methods for non-destructively determining parameters of a doped semiconductor material by, for example: applying an excitation to a surface of the semiconductor material to photogenerate minority carriers in a region of the semiconductor material; presenting an electric field across the region of the semiconductor material; measuring photoluminescence produced by recombination of the photogenerated minority carriers; and using the photoluminescence measurements to compute one or more parameters of the doped semiconductor material. Applying an excitation may involve using a laser to photogenerate minority carriers in the semiconductor material. The laser may be a pulsed or CW laser. Measuring photoluminescence may involve using a camera to image the surface of the semiconductor material, or scanning a fiber-optic probe across the surface of the semiconductor material. Computing one or more parameters of the semiconductor material may involve one or more of: computing the minority carrier mobility of the semiconductor material; computing the saturation drift velocity of minority carriers in the semiconductor material; computing the diffusion constant of minority carriers in the semiconductor material; computing the recombination lifetime of minority carriers in the semiconductor material; and/or computing the effective temperature of the semiconductor material. Additionally, a magnetic field may be presented across the region of the semiconductor material, thereby enabling computation of the effective mass of minority carriers in the semiconductor material. Preferably, computing one or more parameters of the semiconductor material involves computing a plurality of parameters using the same photoluminescence measurements.

Again, generally speaking, and without intending to be limiting, another aspect of the invention relates to systems for non-destructively testing a sample of semiconductor material comprising, for example: first and second probes for applying a bias voltage across a region of the semiconductor material; a laser source, focused to spot illuminate and photogenerate minority carriers in the biased region of the semiconductor material; an optical detection unit, positioned to detect photoluminescence from recombining minority carriers in the biased region of the semiconductor material; and a computer, programmed to compute one or more parameters of the semiconductor material based on measurements made by the optical detection unit. The optical detection unit may comprise a CCD camera, or a scanned, single-mode optical fiber.

Once again, generally speaking, and without intending to be limiting, another aspect of the invention relates to methods for in-line parameter testing during manufacture of a semiconductor device by, for example: processing a layer of doped semiconductor material; performing a non-destructive, in-line test of one or more parameters of the layer by: photogenerating minority carriers in the layer, measuring the distribution of recombining minority carriers by detecting optical illuminations emanating from a surface of the layer, and using the measurements to compute the one or more parameters of the layer; then, using one or more of the computed parameter(s) to control the manufacturing process. Using one or more of the computed parameter(s) to control the manufacturing process may involve aborting further manufacturing steps if one or more of the parameters exceeds predetermined tolerance(s), or using one or more of the computed parameter(s) to adjust future manufacturing process step(s).

### BRIEF DESCRIPTION OF THE FIGURES

Aspects of the present invention are illustrated in the accompanying set of figures, in which:

FIG. 1 depicts an exemplary parameter measurement apparatus in accordance with the invention;

FIG. 2A exemplifies the spatial distribution and temporal decay of a photogenerated minority carrier packet, in the absence of a lateral electric field;

FIG. 2B exemplifies the temporal intensity response of a recombining photogenerated minority carrier packet;

FIG. 3 exemplifies the spatial distribution and temporal decay of a photogenerated minority carrier packet, in the presence of a non-zero lateral electric field;

FIG. 4 contrasts the various spatial intensity profiles of a photogenerated minority carrier packet, under the influence of various non-zero electric fields; and,

FIG. 5 depicts illustrative program modules used in connection with the instant invention.

### DESCRIPTION OF ILLUSTRATIVE EMBODIMENT(S)

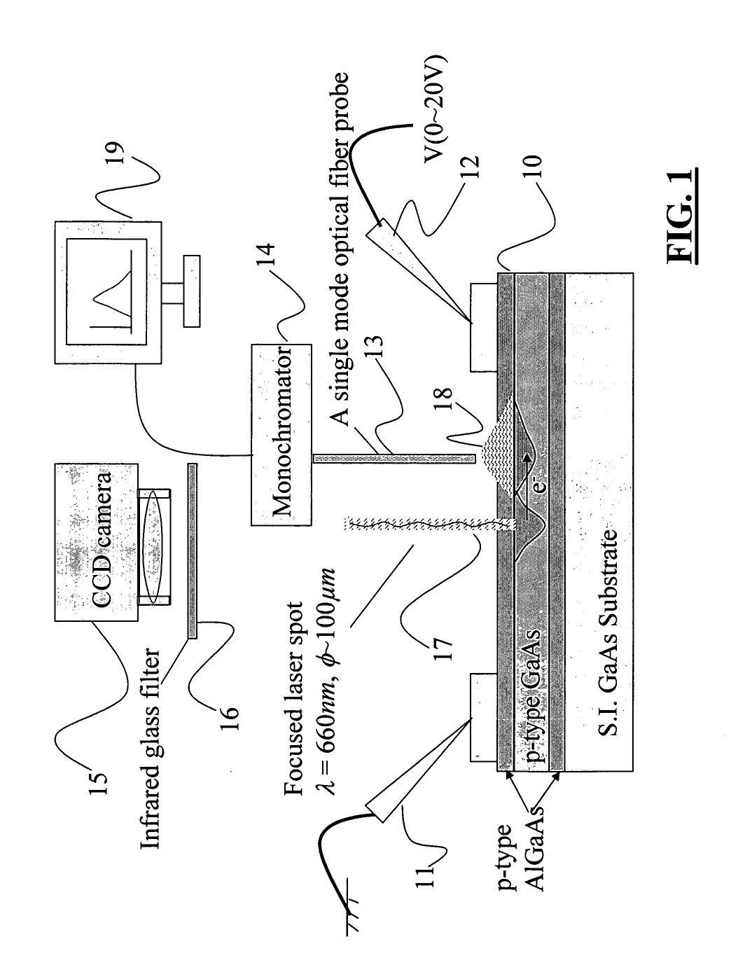

Referring first to FIG. 1, an exemplary semiconductor parameter test apparatus includes means (not illustrated) for generating a laser spot 17 on the surface 10 of a semiconductor material (although illustrated with respect to a p-type semiconductor material, those skilled in the art will immediately recognize that the invention is equally applicable to n-type materials). When laser spot 17 hits the p-type material, it photoexcites a packet of minority carriers (electrons) near the surface of the material. [An alternative embodiment uses direct electron injection with an e-beam to similarly excite a packet of minority carriers near the surface of the material.] An electric field, created between bias electrodes 11-12, drifts the packet of photogenerated electrons as they recombine, thus creating a characteristic illumination pattern 18 at the surface of the semiconductor material.

An optical collection system, illustratively depicted as a single-mode fiber 13 coupled to a monochromator 14 (and alternatively depicted as a CCD camera 15 with an optional IR filter 16), measures the characteristic illumination pattern 18 created by the photogeneration-diffusion-drift-recombination processes near the semiconductor surface. A programmed computer 19 analyzes the measured illumination patter 18 to compute one or more of the semiconductor's material parameters.

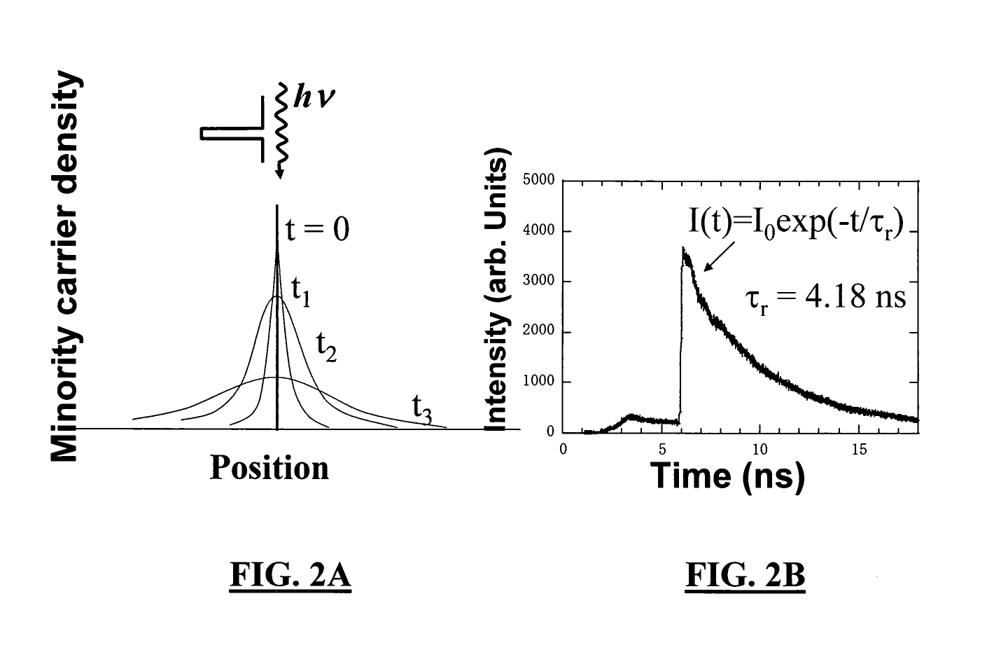

Exemplary semiconductor diffusion, recombination, and diffusion-drift-recombination processes are depicted in FIGS. 2A, 2B, 3, and 4. FIG. 2A shows an exemplary time sequence of a diffusing and recombining photogenerated minority carrier packet at the surface of a semiconductor material. FIG. 2B shows intensity as a function of time for a recombining photogenerated minority carrier packet. Such intensity decays in accordance with the formula:
I(t)=I₀exp(−t/τᵣ)

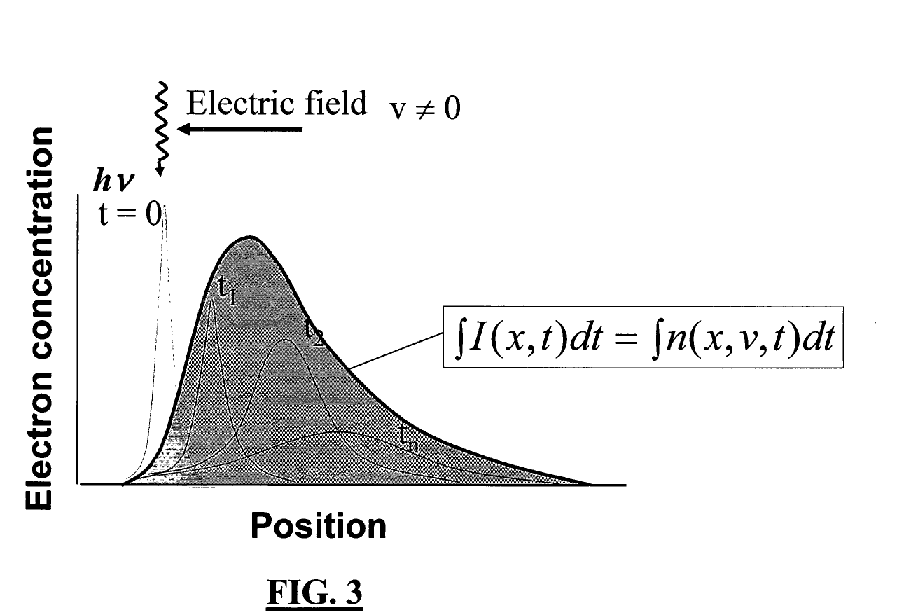

FIG. 3 shows the process of FIG. 1, but with an applied non-zero electric field. As depicted, this process operates in accordance with the following formulas:

$$\int I ( x , t ) ⅆ t = \int n ( x , v , t ) ⅆ t$$

$$n ( x , v , t ) = \frac{{N}_{e}}{\sqrt{4 π Dt}} exp ( \frac{- {( x - vt )}^{2}}{4 Dt} ) exp ( - t / {τ}_{r} )$$

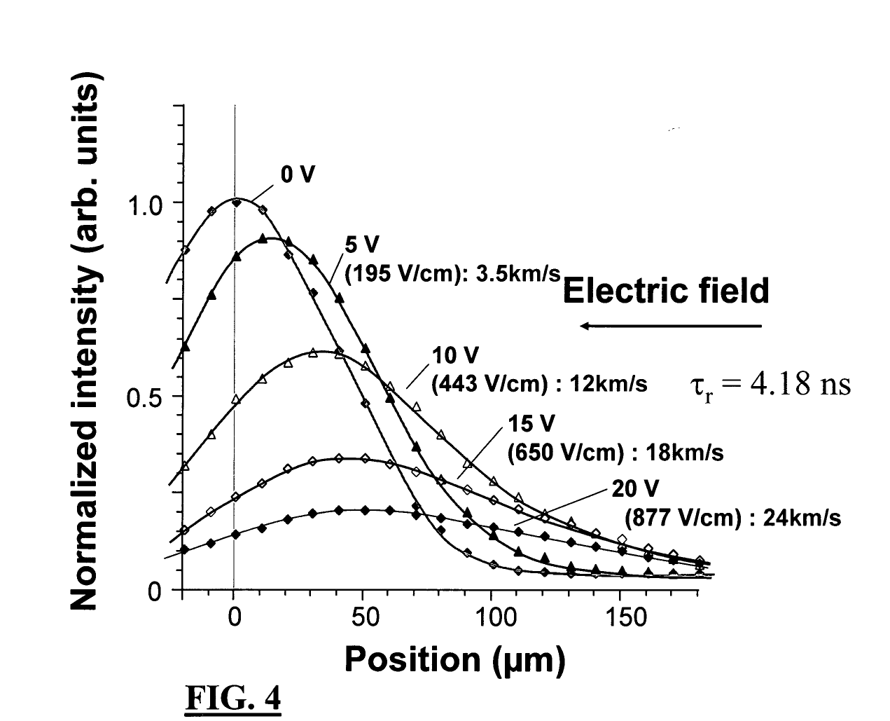

Finally, FIG. 4 compares measured and formula-matched results for a drift-diffusion-recombination process under several applied bias conditions. As can be seen, parameters of the above formulas can be matched (using a programmed computer) to produce excellent agreement with measured illumination profiles.

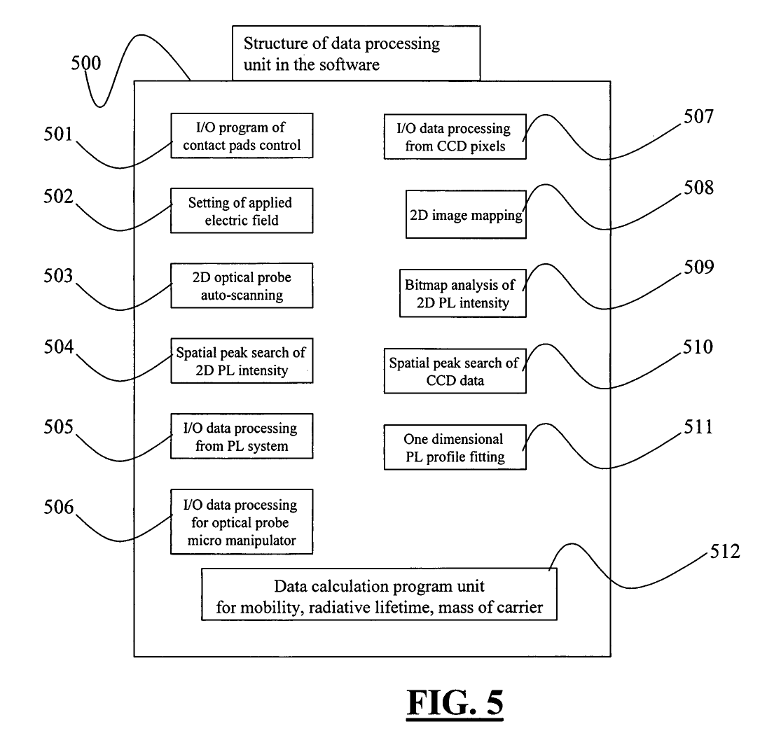

FIG. 5 illustrates an exemplary structure for modular program code 500 used to control and/or carry out various acts related to the invention. Program code 500 preferably contains a plurality of modules, such as:
a module 501 to control the I/O with testing pads;
a module 502 to control application of an electric field to the region under test;
a module 503 to control 2D optical probe scanning;
a module 504 to search out and identify the spatial intensity peak in the measured 2D photoluminescence pattern;
a module 505 that controls I/O related to acquisition of photoluminescence data;
a module 506 that controls I/O related to the fiber optic probe;
a module 507 that processes pixels from the CCD camera;
a module 508 to perform 2D image mapping;
a module 509 that performs bitmap analyses on 2D photoluminescence image data;
a module 510 to identify the spatial intensity peak in a 2D CCD photoluminescence image;
a module 511 to perform 1D photoluminescence profile fitting; and/or,
a data calculation unit to compute requested parameters of a semiconductor material from measured photoluminescence data.

In addition, the invention may also include process control (RtR) code to adjust and/or optimize manufacturing process controls based on parameters computed from in-line photoluminescence measurements.

What is claimed is:

1. A method for non-destructively determining parameters of a doped semiconductor material, comprising:
applying an excitation to a surface of the semiconductor material to photogenerate minority carriers in a region of the semiconductor material;
presenting an electric field across said region of the semiconductor material;
measuring photoluminescence produced by recombination of said photogenerated minority carriers; and,
using the photoluminescence measurements to compute one or more parameters of said doped semiconductor material.

2. A method, as defined in claim 1, wherein applying an excitation comprises using a laser to photogenerate minority carriers in the semiconductor material.

3. A method, as defined in claim 2, wherein applying an excitation comprises using a pulsed laser to photogenerate minority carriers in the semiconductor material.

4. A method, as defined in claim 2, wherein applying an excitation comprises using a CW laser to photogenerate minority carriers in the semiconductor material.

5. A method, as defined in claim 1, wherein measuring photoluminescence comprises using a camera to image the surface of the semiconductor material.

6. A method, as defined in claim 1, wherein measuring photoluminescence comprises scanning a fiber-optic probe across the surface of the semiconductor material.

7. A method, as defined in claim 1, wherein computing one or more parameters of the semiconductor material comprises computing the minority carrier mobility of the semiconductor material.

8. A method, as defined in claim 1, wherein computing one or more parameters of the semiconductor material comprises computing the saturation drift velocity of minority carriers in the semiconductor material.

9. A method, as defined in claim 1, wherein computing one or more parameters of the semiconductor material comprises computing the diffusion constant of minority carriers in the semiconductor material.

10. A method, as defined in claim 1, wherein computing one or more parameters of the semiconductor material comprises computing the recombination lifetime of minority carriers in the semiconductor material.

11. A method, as defined in claim 1, wherein computing one or more parameters of the semiconductor material comprises computing the effective temperature of the semiconductor material.

12. A method, as defined in claim 1, further comprising presenting a magnetic field across said region of the semiconductor material.

13. A method, as defined in claim 12, wherein computing one or more parameters of the semiconductor material comprises computing the effective mass of minority carriers in the semiconductor material.

14. A method, as defined in claim 1, wherein computing one or more parameters of the semiconductor material comprises computing a plurality of parameters using the same photoluminescence measurements.

15. A system for non-destructively testing a sample of semiconductor material, the system comprising:
first and second probes for applying a bias voltage across a region of the semiconductor material;
a laser source, focused to spot illuminate and photogenerate minority carriers in the biased region of the semiconductor material;
an optical detection unit, positioned to detect photoluminescence from recombining minority carriers in the biased region of the semiconductor material; and,
a computer, programmed to compute one or more parameters of the semiconductor material based on measurements made by the optical detection unit.

16. A system, as defined in claim 15, wherein said optical detection unit comprises a CCD camera.

17. A system, as defined in claim 15, wherein said optical detection unit comprises a scanned, single-mode optical fiber.

18. A method for in-line parameter testing during manufacture of a semiconductor device, the method comprising:
processing a layer of doped semiconductor material;
performing a non-destructive, in-line test of one or more parameters of said layer by:
photogenerating minority carriers in said layer;
measuring a distribution of recombining minority carriers by detecting optical illuminations emanating from a surface of said layer; and,
using said measurements to compute the one or more parameters of the layer; and,
using one or more of the computed parameter(s) to control the manufacturing process.

19. A method, as defined in claim 18, wherein using one or more of the computed parameter(s) to control the manufacturing process comprises aborting further manufacturing steps if one or more of said parameters exceeds predetermined tolerance(s).

20. A method, as defined in claim 18, wherein using one or more of the computed parameter(s) to control the manufacturing process comprises using one or more of the computed parameter(s) to adjust future manufacturing process step(s).
